(19) United States
(12) Patent Application Publication
(10) Pub. No.: US 2021/0033900 A1
(43) Pub. Date: Feb. 4, 2021

(54) MODULAR FLAT PANEL DISPLAY

(71) Applicant: V-Finity International, George Town (KY)

(72) Inventor: Heng Liu, Sunnyvale, CA (US)

(21) Appl. No.: 16/923,895

(22) Filed: Jul. 8, 2020

Related U.S. Application Data
(60) Provisional application No. 62/881,634, filed on Aug. 1, 2019.
(60) Provisional application No. 62/885,425, filed on Aug. 12, 2019.

(51) Int. Cl. G02F 1/1339; G02F 1/1335; H01L 27/32; H01L 51/52; H01L 51/56

(52) U.S. Cl. CPC G02F 1/1339; G02F 1/133516; H01L 51/56; H01L 51/524; H01L 27/322

(57) ABSTRACT

A liquid crystal display comprises a first panel. The first panel comprises a first layer comprising an array substrate; a second layer of liquid crystal cells having a sealant at an edge of the second layer; a third layer of color filters comprising sets of filters with first non-emitting spaces between each set; and an edge of the third layer having a second non-emitting space having a length less than (e.g., half) a length of one of the first non-emitting spaces. The sealant and the second non-emitting space have an approximate equal length. An organic light-emitting diode (OLED) display can be constructed similarly with edge sealant on an OLED layer having a length less than (e.g., half) a length of a non-emitting area in the OLED layer.

### CROSS REFERENCE TO RELATED APPLICATIONS

This application claims priority to and incorporates by reference U.S. patent application Ser. No. 62/881,634 filed Aug. 1, 2019 and U.S. patent application Ser. No. 62/885,425 filed Aug. 12, 2019.

### TECHNICAL FIELD

The present disclosure generally relates to flat panel displays and more particularly, but not exclusively, to providing a modular flat panel display with a non-emitting edge having a length less than (e.g., ½) a length of a non-emitting space between pixels.

### BACKGROUND

Multiple smaller liquid crystal displays (LCD) and organic light-emitting diode (OLED) displays can be combined to form a larger display, especially when desired total display size exceeds 100 inches. This modular approach to form a large display is less expensive and less complex than generating a single display due to the sheer size of a large display. However, this modular approach leads to dark seams between each smaller display, which are visible to a viewer.

### SUMMARY

In an embodiment, a liquid crystal display comprises a first panel. The first panel comprises: a first layer comprising an array substrate; a second layer of liquid crystal cells having a sealant at an edge of the second layer; and a third layer of color filters comprising sets of filters with first non-emitting spaces between each set. An edge of the third layer has a second non-emitting space having a length less than a length of one of the first non-emitting spaces.

A method of manufacturing the liquid crystal display comprises providing a first LCD panel. The LCD panel comprises a first layer comprising an array substrate; a second layer of liquid crystal cells having a sealant at an edge of the second layer; a third layer of color filters comprising sets of filters with first non-emitting spaces between each set; and an edge of the third layer having a second non-emitting space having a length less than a length of one of the first non-emitting spaces. The method further comprises creating a via in the array substrate and providing electrical conducting material inside the via; creating an interconnect on a first surface of the array substrate electrically coupling the via to thin film transistors on a second surface of the array substrate; and bonding LCD driver circuitry to the interconnect.

In an embodiment, an organic light-emitting diode (OLED) display, comprises a first panel. The first panel comprises: a first layer comprising an array substrate; a second layer of OLEDs comprising sets of OLEDs with non-emitting spaces between each set, the second layer further having an edge non-emitting space at an edge of the second layer. The edge non-emitting space has a length less than a length of one of the non-emitting spaces.

In an embodiment, a method of manufacturing the organic light-emitting diode (OLED) display comprises providing the first panel; creating a via in the first layer and providing the via with electrical conducting material; creating an interconnect on a first surface of the first layer connected to the via; and bonding OLED driver circuitry to the interconnect.

### BRIEF DESCRIPTION OF THE DRAWINGS

To more easily identify the discussion of any particular element or act, the most significant digit or digits in a reference number refer to the figure (“FIG.”) number in which that element or act is first introduced.

FIG. 1 depicts a cross section of a liquid crystal display according to an embodiment;

FIG. 2 depicts a cross section of an LCD with backlight according to an embodiment;

FIG. 3 depicts a cross section of an OLED display according to an embodiment;

FIG. 4A and 4B depict plan view of joining of two displays to form a larger display;

FIG. 5 depicts a flowchart of a method of manufacturing an LCD according to an embodiment;

FIG. 6 depicts a flowchart of a method manufacturing an OLED display according to an embodiment; and

FIG. 7 depicts a cross section of a OLED display according to an embodiment.

### DETAILED DESCRIPTION

The description that follows includes systems, methods, techniques, that embody illustrative embodiments of the disclosure. In the following description, for the purposes of explanation, numerous specific details are set forth in order to provide an understanding of various embodiments of the inventive subject matter. It will be evident, however, to those skilled in the art, that embodiments of the inventive subject matter may be practiced without these specific details. In general, well-known instruction instances, protocols, structures, and techniques are not necessarily shown in detail.

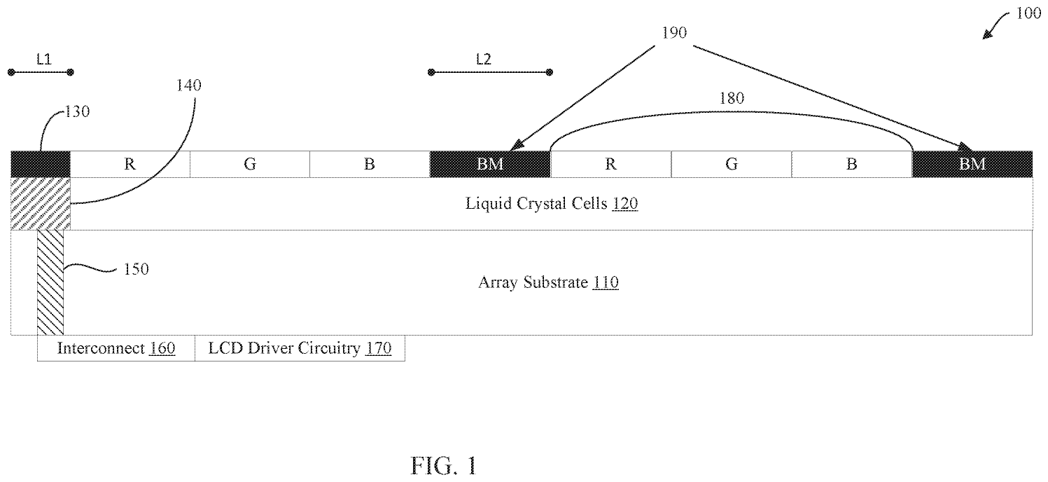

FIG. 1 depicts a cross section of a liquid crystal display 100 according to an embodiment. The liquid crystal display 100 comprises a first layer 110 comprising an array substrate (including thin film transistors (TFTs) not shown); a second layer 120 of liquid crystal cells having a sealant 140 at an edge of the second layer 120; a third layer of color filters comprising sets 180 of filters (e.g., red, green and blue) with first non-emitting spaces 190 between each set 180. An edge of the third layer has a second non-emitting space 130 having a length L1 less than a length L2 of one of the first non-emitting spaces 190. In an embodiment, the first and second non-emitting spaces 190 and 130 comprise black matrix. The sealant 140 and the second non-emitting space 130 have an approximate equal length (e.g., +/−10%). In another embodiment, the sealant length is larger than L1. At a maximum, sealant length would be ½ of L2. Note for ease of description, other elements of the LCD 100 known to one of ordinary skill in art, e.g., a polarizer, films, cover glass, etc. are not shown or described.

In an embodiment the second non-emitting space 130 has a length L1 of approximately (e.g., +/−10%) half of a length L2 of one of the first non-emitting spaces 190. In an embodiment, L1 and be approximately 50-400 um and L2 approximately 100-800 um. For example, for a 4K 150″, the pixel pitch is 0.837 mm (837 um). L1 can be 200 um, L2 can be 400 um; or with larger emitting area L1:100 um, L2 200 um. For a 4K 100″, the pixel pitch is 0.558 mm (558 um), L1 can be 150 um, L2 can be 300 um. In an embodiment, the emitting area is at least about 25% in a pixel, for example, 50%.

The LCD 100 also comprises a though hole conductive via 150 in the first layer 110 electrically connected to LCD driver circuitry 170 on a first surface of the first layer 110 and the thin film transistors on a second surface of the first layer 110. The LCD driver circuitry 170 can be connected to the via 150 via an interconnect 160 also mounted on the first surface of the first layer 110 or located elsewhere and connect to the via 150 by flexible cable.

The via 150 can be conductor-filled or metal coated on an inside surface and bring the circuit connection to the back (first surface) of the array substrate 110. A filler in the via 150 can be metal, Ag-epoxy or other electrical conducting materials. The via 150 can be made by laser drilling, wet or dry etching, or combination. The via may be located underneath first and/or second non-emitting spaces 190 and 130 so as to not block light at sets 180. Note that while a single via 150 is illustrated, the LCD 100 may have multiple vias (e.g., one via per pixel). The via can be filled by dispensing, printing, electro-plating, vapor deposition, photolithography, direct writing and spraying of filler materials.

Interconnection circuitry 160 can be made by photolithography like semiconductor IC process or printed circuit board process. For example, the interconnect can be made by dispensing, printing, electro-plating, vapor deposition, photolithography, direct writing and masked spraying of conductive materials. Electronic components can be bonded to the printed circuit glass. Sealant structure 140 can he made by dispensing, screen printing, silk printing, photolithographic printing, etc. The Array substrate 110 can be glass, polymer, ceramic, silicon, etc.

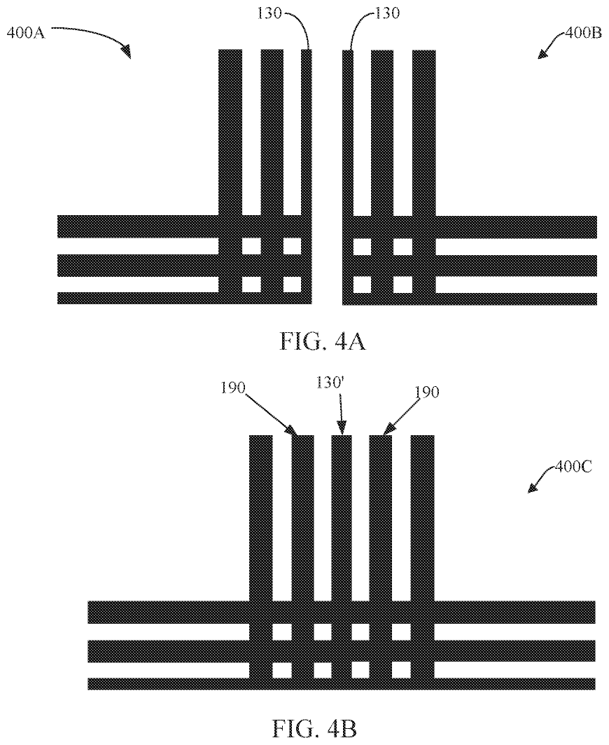

In an embodiment, each display 100 of a video wall (multi-panel display) can have a number of pixels needed to achieve final 4k resolution over an entire video wall comprising a plurality of displays 100. If the module 100 has a very high pixel resolution, the non-emitting space 190 is very small. For example a 55″ 2K LCD module the non-emitting space 190 between pixel is only about 100 um (pixel pitch is about 600 um). In an embodiment, a module with the final display resolution, say 4k 165″ (equivalent to 3×3 LCD wall using 55″ module), the pixel pitch of each module 100 need only be 900 um. The non-emitting space 130 at the edge can be made to 200 um making a seamless connection possible as shown in FIG. 4A and 4B.

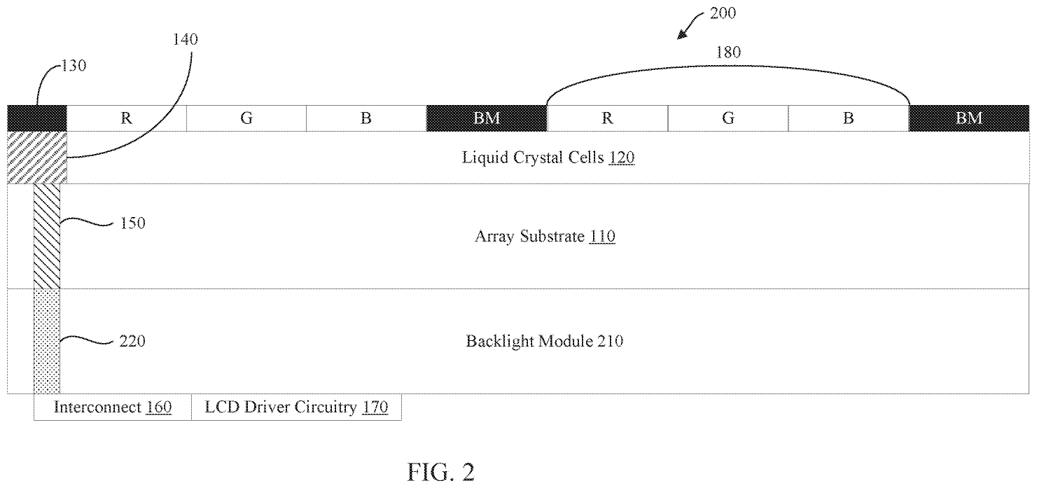

FIG. 2 depicts a cross section of an LCD 200 with a backlight 210 according to an embodiment. The LCD 200 is substantially similar to the LCD 100 except it includes a backlight module 210 on the first surface of the first layer 110 and accordingly, the interconnect 160 and LCD driver circuitry are mounted on a back surface of the backlight module 210. The module 210 also includes an interface contact 220 between the via 150 and the interconnect 160.

The backlight module 210 can be a printed circuit board (PCB) with OLED or LED (light emitting diode) mounted on the top and interface contacts to the via 150 in the array substrate 110. The PCB material can be FR4, BT, polymer or glass, etc. Note for ease of description, other elements of the LCD 100 known to one of ordinary skill in art, e.g., a polarizer, films, cover glass, etc. are not shown or described.

The backlight module 210 can be made into the same panel size as the first layer 110 or smaller and can be bonded to the first layer 110 by solder joint, eutectic bonding, or ACF/ACP(anisotropic conductive film or paste) bonding.

In an embodiment, the backlight module 210 can also be an LED or OLED display with self-emitting pixels.

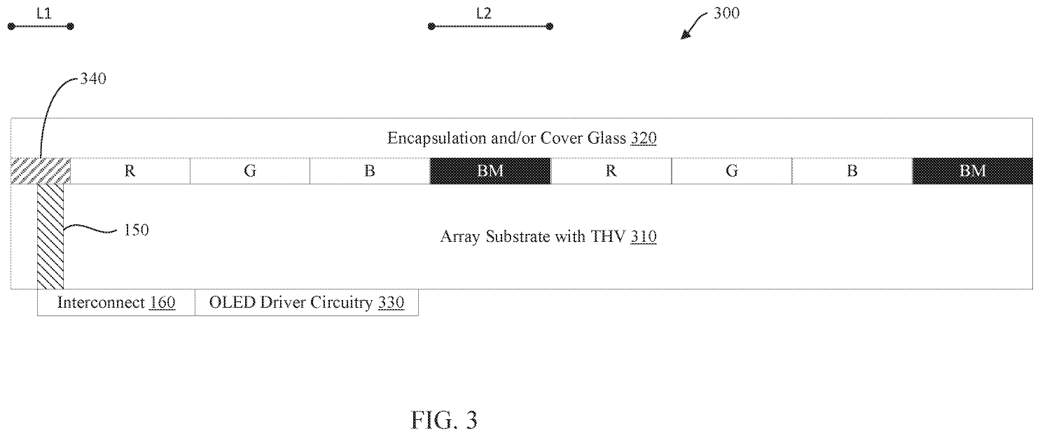

FIG. 3 depicts a cross section of an OLED display 300 according to an embodiment. The OLED display 300, comprises a first layer comprising an array substrate 310, which can be similar to the array substrate layer 110; a second layer of OLEDs comprising sets of OLEDs (marked as R, G, and B) with non-emitting spaces between each set (marked as BM for Black Matrix but it can be another insulator with some transparency), the second layer further has an edge non-emitting space 340 at an edge of the second layer; and a third layer 320 of glass or polymer type encapsulant to prevent air or moisture contact to OLED layer. The edge non-emitting space 140 has a length L1 less than a length L2 of one of the inside non-emitting spaces. The space 340 can comprise same or similar material to the non-emitting spaces labelled BM.

The OLED display 300 can also further comprises a conductive via 150 connecting an interconnect 160 to the second layer. The interconnect 160 is located at a first surface of the first layer 310 and the via 150 can be located anywhere of the array substrate 310 since it does not block any light emitting from the OLED itself. The OLED display also includes OLED driver circuitry 330 coupled to the interconnect 150, and can be located elsewhere and connect to the via 150 by flexible cable. Note for ease of description, components of display 300 known to one of ordinary skill in the art are not illustrated, e.g. cathode and anode.

The conductive via 150 is through the first layer 310.

The edge non-emitting space 140 length L1 can be reduced to approximately (+/−10%) half the length L2 of the inside non-emitting space so that when two modules are connected the combined length is the same as the inside non-emitting space length L2. The via 150 (also referred to as a through hole via—THV) brings a circuit connection to the back of the array substrate 310

The array substrate 310 may be very thin material and there can be a more rigid substrate such as PCB inserted between the array substrate 310 and the OLED driver circuitry 330.

FIG. 4A and 4B depict a plan view of joining of two displays (also referred to as panels) 400A and 400B to form a larger display 400C. Edges of the panels 400A and 400B join together so that a combined edge is approximately equal in length to other non-emitting areas within the combined display 400C. The panels 400A and 400B can be the displays 100, 200, and/or 300. When the panels 400A and B are disposed adjacent each other a combined length of the second non-emitting space 130′ of the first and second panels is approximately equal to the length of one of the first non-emitting spaces 190. When the panels 400A and B comprise the OLED displays 300, a combined length of edge non-emitting space 140 on respective edges is equal to the length of one of the inside non-emitting spaces L2. Note that in an embodiment, non-emitting spaces 130 at edges of each panel can be of different lengths as long as when combined total length is approximately equal to the length of non-emitting spaces 190. That is, L1 can vary among panels as long as when joined, the two L1s are equal approximately (+/−10%) to L2. For example, a first L1 when may be ¼ length of L2 and a second L1 is ¾ length of L2.

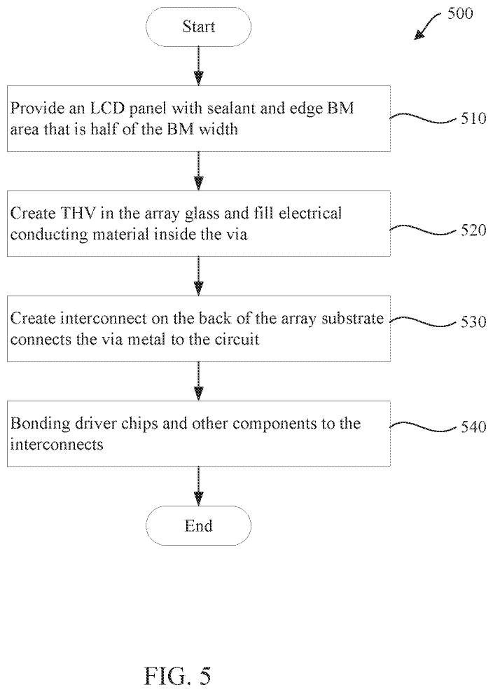

FIG. 5 depicts a flowchart of a method 500 of manufacturing an LCD 100 or 200 according to an embodiment. The method 500 comprises providing (510) a first LCD panel, such as panel 100 or 200. The sealant 140 and non-emitting space 130 (i.e., edge area) have a length L1 less than (e.g., approximately half) of the non-emitting space 190 length L2. Creating (520) a conductive via 150 in the array substrate 110 and filling electrical conducting material inside the via 150 or metal coating an inside surface of the via 150. Creating (530) an interconnect 160 on a first surface of the array substrate 110 and connecting the via to thin film transistors on a second surface of the array substrate 110. Bonding (540) LCD driver circuitry 170 to the interconnect 150. The method 500 may further comprise positioning a backlight module 210 on a surface of the first layer 110 and an interface contact 220 between the via 150 and the interconnect 160.

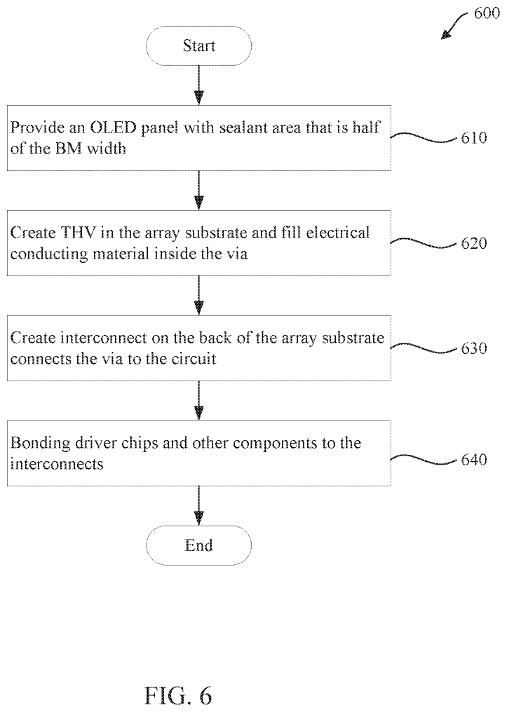

FIG. 6 depicts a flowchart of a method 600 of manufacturing an OLED display 300 according to an embodiment. The method 600 comprises providing (610) a first OLED panel where the edge non-emitting space 140 length L1 is less than an inside non-emitting space length L2 (e.g., approximately half the length); creating (620) a conductive via in the first layer and filling the via with electrical conducting material or metal coating an inside surface; creating (630) an interconnect on a first surface of the first layer connected to the via; and bonding (640) OLED driver circuitry to the interconnect. The via may be located anywhere of the array substrate 310 since they do not block light at any emitting space.

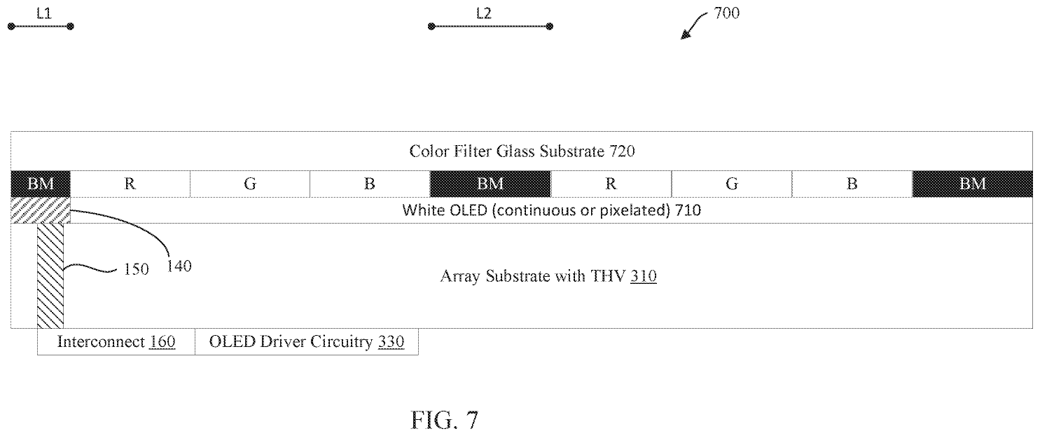

FIG. 7 depicts a cross section of an OLED display 700 according to an embodiment. The OLED display 700 is similar to the OLED display 300 and includes a white OLED 710 can be a continuous layer while the TFT driving circuit in each pixel light up only the portion of OLED electrically connected to it and other area will not light up since OLED has very large lateral resistance that electrical current does not flow in that direction.

The following examples describe various embodiments of methods, machine-readable media, and systems (e.g., machines, devices, or other apparatus) discussed herein.

1. A liquid crystal display, comprising a first panel, the first panel comprising:

a first layer comprising an array substrate;

a second layer of liquid crystal cells having a sealant at an edge of the second layer;

a third layer of color filters comprising sets of filters with first non-emitting spaces between each set; and

an edge of the third layer having a second non-emitting space having a length less than a length of one of the first non-emitting spaces.

2. The liquid crystal display of example 1, wherein the second non-emitting space has a length of approximately half of a length of one of the first non-emitting spaces.

3. The liquid crystal display of any of the preceding examples, further comprising a backlight module on a surface of the first layer and an interface contact between a via and an interconnect.

4. The liquid crystal display of any of the preceding examples, further comprising: a through hole via in the first layer electrically connected to an external LCD driver circuitry and thin film transistors on a second surface of the first layer.

5. The liquid crystal display of any of the preceding examples, wherein the first and second non-emitting spaces comprise black matrix.

6. The liquid crystal display of any of the preceding examples, further comprising a second panel substantially similar to the first panel and disposed adjacent the first panel such that a combined length of the second non-emitting space of the first and second panels is approximately equal to the length of one of the first non-emitting spaces.

7. An organic light-emitting diode (OLED) display, comprising a first panel, the first panel comprising:

a first layer comprising an array substrate;

a second layer of OLEDs comprising sets of OLEDs with non-emitting spaces between each set, the second layer further having an edge non-emitting space at an edge of the second layer;

wherein the edge non-emitting space has a length less than a length of one of the non-emitting spaces.

8. The organic light-emitting diode (OLED) display of any of the preceding examples, further comprising:

a conductive via electrically coupling an interconnect to the second layer, the interconnect located at a first surface of the first layer; and OLED driver circuitry electrically coupled to the interconnect.

9. The organic light-emitting diode (OLED) display of any of the preceding examples, wherein the conductive via is through the first layer.

10. The organic light-emitting diode (OLED) display of any of the preceding examples further comprising a third layer, wherein the third layer comprises one or more color filters.

11. The organic light-emitting diode OLED) display of any of the preceding examples, further comprising a second panel substantially similar to the first panel, the second panel disposed adjacent to the first panel such that a combined length of edge non-emitting space on respective edges is equal to the length of one of the non-emitting spaces.

12. A method of manufacturing a liquid crystal display, comprising: providing a first LCD panel including:

a first layer comprising an array substrate;

a second layer of liquid crystal cells having a sealant at an edge of the second layer;

a third layer of color filters comprising sets of filters with first non-emitting spaces between each set; and

an edge of the third layer having a second non-emitting space having a length less than a length of one of the first non-emitting spaces;
creating a via in the array substrate and providing electrical conducting material inside the via;
creating an interconnect electrically coupling the via to thin film transistors on a first surface of the array substrate; and
bonding LCD driver circuitry to the interconnect.

13. The method of any of the preceding examples, wherein the second non-emitting space has a length of approximately half of a length of one of the first non-emitting spaces.

14. The method of any of the preceding examples, further comprising positioning a backlight module on a second surface of the first layer and an interface contact between the via and the interconnect.

15. The method of any of the preceding examples, wherein the first and second non-emitting spaces comprise black matrix.

16. The method of any of the preceding examples, further comprising generating a second LCD panel and aligning the first LCD panel adjacent the second LCD panel such that the second non-emitting space of the third layer of each panel have a combined length of approximately equal to a length of one of the first non-emitting spaces.

17. A method of manufacturing the organic light-emitting diode (OLED) display of any of the preceding examples, comprising:

providing the first panel;

creating a via in the first layer and providing the via with electrical conducting material;

creating an interconnect on a first surface of the first layer connected to the via; and

bonding OLED driver circuitry to the interconnect.

18. The method of any of the preceding examples, wherein the via is located beneath one of the non-emitting spaces.

19. The method of any of the preceding examples, further comprising providing a second panel substantially similar to the first panel, the second panel disposed adjacent to the first panel such that a combined length of the edge non-emitting space on respective edges is equal to the length of one of the non-emitting spaces.

Although the subject matter has been described with reference to specific example embodiments, it will be evident that various modifications and changes may be made to these embodiments without departing from the broader scope of the disclosed subject matter. Accordingly, the specification and drawings are to be regarded in an illustrative rather than a restrictive sense. The accompanying drawings that form a part hereof show by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Description, therefore, is not to be taken in a limiting sense, and the scope of various embodiments is defined only by any appended claims, along with the full range of equivalents to which such claims are entitled.

Such embodiments of the inventive subject matter may be referred to herein, individually and/or collectively, by the term “invention” merely for convenience and without intending to voluntarily limit the scope of this application to any single invention or inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

1. A liquid crystal display, comprising a first panel, the first panel comprising:
a first layer comprising an array substrate;
a second layer of liquid crystal cells having a sealant at an edge of the second layer;
a third layer of color filters comprising sets of filters with first non-emitting spaces between each set;
an edge of the third layer having a second non-emitting space having a length less than a length of one of the first non-emitting spaces; and
a through hole via in the first layer electrically connected to an external LCD driver circuitry and thin film transistors on a second surface of the first layer.

2. The liquid crystal display of claim 1, wherein the second non-emitting space has a length of approximately half of a length of one of the first non-emitting spaces.

3. The liquid crystal display of claim 1, further comprising a backlight module on a surface of the first layer and an interface contact between a via and an interconnect.

4. The liquid crystal display of claim 1, wherein the through hole via is beneath the sealant.

5. The liquid crystal display of claim I, wherein the first and second non-emitting spaces comprise black matrix.

6. The liquid crystal display of claim 1, further comprising a second panel substantially similar to the first panel and disposed adjacent the first panel such that a combined length of the second non-emitting space of the first and second panels is approximately equal to the length of one of the first non-emitting spaces.

7. An organic light-emitting diode (OLED) display, comprising a first panel, the first panel comprising:
a first layer comprising an array substrate;
a second layer of OLEDs comprising sets of OLEDs with non-emitting spaces between each set, the second layer further having an edge non-emitting space at an edge of the second layer;
wherein the edge non-emitting space has a length less than a length of one of the non-emitting spaces;
a conductive via electrically coupled an interconnect to the second layer, the interconnect located at a first surface of the first layer; and
OLED driver circuitry electrically coupled to the interconnect.

8. The organic light-emitting diode (OLED) display of claim 7, wherein the OLED driver circuitry is electrically coupled to the interconnect through a cable.

9. The organic light-emitting diode (OLED) display of claim 8, wherein the conductive via is through the first layer.

10. The organic light-emitting diode (OLED) display of claim 7 further comprising a third layer, wherein the third layer comprises one or more color filters.

11. The organic light-emitting diode (OLED) display of claim 7, further comprising a second panel substantially similar to the first panel, the second panel disposed adjacent to the first panel such that a combined length of edge non-emitting space on respective edges is equal to the length of one of the non-emitting spaces.

12. A method of manufacturing a liquid crystal display, comprising:
providing a first LCD panel including:
a first layer comprising an array substrate;
a second layer of liquid crystal cells having a sealant at an edge of the second layer;
a third layer of color filters comprising sets of filters with first non-emitting spaces between each set; and
an edge of the third layer having a second non-emitting space having a length less than a length of one of the first non-emitting spaces;
creating a via in the array substrate and providing electrical conducting material inside the via;
creating an interconnect electrically coupling the via to thin film transistors on a first surface of the array substrate; and
bonding LCD driver circuitry to the interconnect.

13. The method of claim 12, wherein the second non-emitting space has a length of approximately half of a length of one of the first non-emitting spaces.

14. The method of claim 12, further comprising positioning a backlight module on a second surface of the first layer and an interface contact between the via and the interconnect.

15. The method of claim 12, wherein the first and second non-emitting spaces comprise black matrix.

16. The method of claim 12, further comprising generating a second LCD panel and aligning the first LCD panel adjacent the second LCD panel such that the second non-emitting space of the third layer of each panel have a combined length of approximately equal to a length of one of the first non-emitting spaces.

17. A method of manufacturing the organic light-emitting diode (OLED) display of claim 7, comprising:
providing the first panel;
creating a via in the first layer and providing the via with electrical conducting material;
creating an interconnect on a first surface of the first layer connected to the via; and
bonding MED driver circuitry to the interconnect.

18. The method of claim 17, wherein the via is located beneath one of the non-emitting spaces.

19. The method of claim 17, further comprising providing a second panel substantially similar to the first panel, the second panel disposed adjacent to the first panel such that a combined length of the edge non-emitting space on respective edges is equal to the length of one of the non-emitting spaces.
